(19) United States
(12) Patent Application Publication
(10) Pub. No.: US 2003/0212940 A1
(43) Pub. Date: Nov. 13, 2003

(54) Interface architecture for embedded field programmable gate array cores

(76) Inventor: Dale Wong, San Francisco, CA (US)

Correspondence Address: RITTER, LANG & KAPLAN LLP, Suite D1, 12930 Saratoga Ave., Saratoga, CA, 95070, US

(21) Appl. No.: 10/270,022

(22) Filed: Oct. 12, 2002

Related U.S. Application Data
(60) Provisional application No. 60/329,818, filed on Oct. 16, 2001.

(51) Int. Cl. G01R 31/28

(52) U.S. Cl. 714/725

(57) ABSTRACT

An interface architecture is presented for Field Programmable Gate Array (FPGA) cores by which an FPGA core can be embedded into an integrated circuit and easily configured and tested without detailed knowledge of the FPGA core. A microcontroller coupled to the FPGA core has a general instruction set that provides access to all resources within the FPGA core. This enables high level services, such as configuration loading, configuration monitoring, built in self test, defect analysis, and debugger support, for the FPGA core upon instructions from a host interface. The host interface, which modifies the instructions from a processor unit, for example, for the microcontroller, provides an adaptable buffer unit to allow the FPGA core to be easily embedded into different integrated circuits.

### CROSS-REFERENCES TO RELATED APPLICATIONS

This patent application claims priority from U.S. Provisional Patent Application No. 60/329,818, filed Oct. 16, 2001, and which is incorporated herein for all purposes.

### BACKGROUND OF THE INVENTION

The present invention is related to configurable interconnection networks in integrated circuits and, in particular, to the FPGA (Field Programmable Gate Array) cores which are embedded in integrated circuits. The FPGA core can provide configurable interconnections between functional blocks, particularly a computing element such as processor core, or itself provide a configurable functional block, in the integrated circuit.

FPGAs are integrated circuits whose functionalities are designated by the users of the FPGA. The user can program the FPGA (hence the term, “field programmable”) to perform the functions desired by the user. The FPGA has an interconnection network between the logic cells and the interconnection network, and the logic cells are configurable to perform the application desired by the user. Typically, one or more FPGAs are connected with other integrated circuits in an electronic system. The FPGA can be configured to provide the desired signal paths between the other integrated circuits and to condition the signals if required. For FPGAs based on SRAM (Static Random Access Memory) cells to hold the configuration bits, the configuration of the FPGA can be changed by the user for multiple applications of the electronic system. For configurable cores based on single-mask customization, the FPGA can only be configured once by the user.

With shrinking geometries in semiconductor technology, FPGAs are beginning to be embedded with functional circuit blocks in ASICs (Application Specific Integrated Circuits). Such elements may include a processor, memory, and peripheral elements in the so-called System-on-a-Chip (SOC), or multi-processor elements of a parallel computing integrated circuit, for example. The main configurable portion of the FPGA, termed an FPGA core, is embedded in the ASIC to configurably interconnect the various functional blocks of the ASIC or to form another functional block of the integrated circuit. This block is programmable by the user (or the manufacturer of the ASIC) to make the integrated circuit flexible in its application.

To program an embedded FPGA core (or an FPGA), configuration bits are used to set the state of switches in the FPGA logic and interconnection paths. Heretofore, JTAG, a defined IEEE 1149.1 standard for testing electronic systems and integrated circuits, serial scan chains in the integrated circuit have been used to carry the configuration bits of the FPGA core programming. To test the integrity of an ASIC having an FPGA core, the core must be configured and then tested. Such configuration and testing of the FPGA core places a heavy responsibility upon the ASIC designer who is typically not the originator of the FPGA core nor even of the other functional blocks of the ASIC. Hence each time an FPGA core is embedded into an integrated circuit, the designer must delve into the details of the particular FPGA core and create specific interfaces and testing routines for the core. This causes delays in the design of the ASIC and raises potential areas for errors and uncertainty in reliability.

The present invention addresses these problems and offers an efficient way for FPGA core to be configured and tested.

### SUMMARY OF THE INVENTION

The present invention provides for an integrated circuit having an FPGA core; an interface adapted to receive commands to configure the FPGA core; and a microcontroller coupled to the FPGA core, the microcontroller configuring the FPGA core responsive to the commands received from the interface. When the integrated circuit has a processor unit for directing operations of the integrated circuit, the interface is adapted to receive the configure commands from the processor unit.

The interface is further adapted to receive commands to test the FPGA core by which the microcontroller tests the FPGA core responsive to the test commands received from the interface. Where the FPGA core has specific features, the microcontroller tests the FPGA core in a predetermined sequence of tests. For example, where the FPGA core has a hierarchical architecture, the predetermined sequence of tests corresponds to the hierarchy of the architecture.

The present invention further provides for a plurality of scan chains coupled to the FPGA core for introducing test vectors into the FPGA core and for receiving test results from the FPGA core responsive to the microcontroller. The scan chains are arranged with respect to predetermined portions of the FPGA core so that a first scan chain introduces a test vector into a portion and a second scan chain receives tests results of the test vector from the portion.

### BRIEF DESCRIPTION OF THE DRAWINGS

FIG. 1 is a block level diagram of an ASIC organized with a processor unit and a host interface for the embedded FPGA core according to one embodiment of the present invention;

FIG. 2 is a block level diagram of the microcontroller of the FIG. 1 ASIC;

FIG. 3 is a representative diagram illustrating the registers for the configuration bits to program the embedded FPGA core of FIG. 1;

FIG. 4A shows scan chains for testing the embedded FPGA core; FIG. 4B illustrates the arrangement of two scan chains for impressing test signals upon and retrieving test result signals from a portion of the embedded FPGA core in accordance with the present invention;

FIG. 5 shows an exemplary multiplexer-based interconnect network architecture of the embedded FPGA core;

FIG. 6A illustrates the bottom level of the hierarchical multiplexer-based interconnect architecture of the embedded FPGA core of FIG. 1; FIG. 6B shows the next higher level, or parent, of the FIG. 6A hierarchical level; FIG. 6C shows the next higher level, or parent, of the FIG. 6B hierarchical level;

FIG. 7 illustrates the input and output multiplexers of the two hierarchical levels of FIG. 6B; and

FIG. 8 shows how the multiplexers of FIG. 7 make a connection between two bottom level units.

### DESCRIPTION OF THE SPECIFIC EMBODIMENTS

General Organization of an ASIC

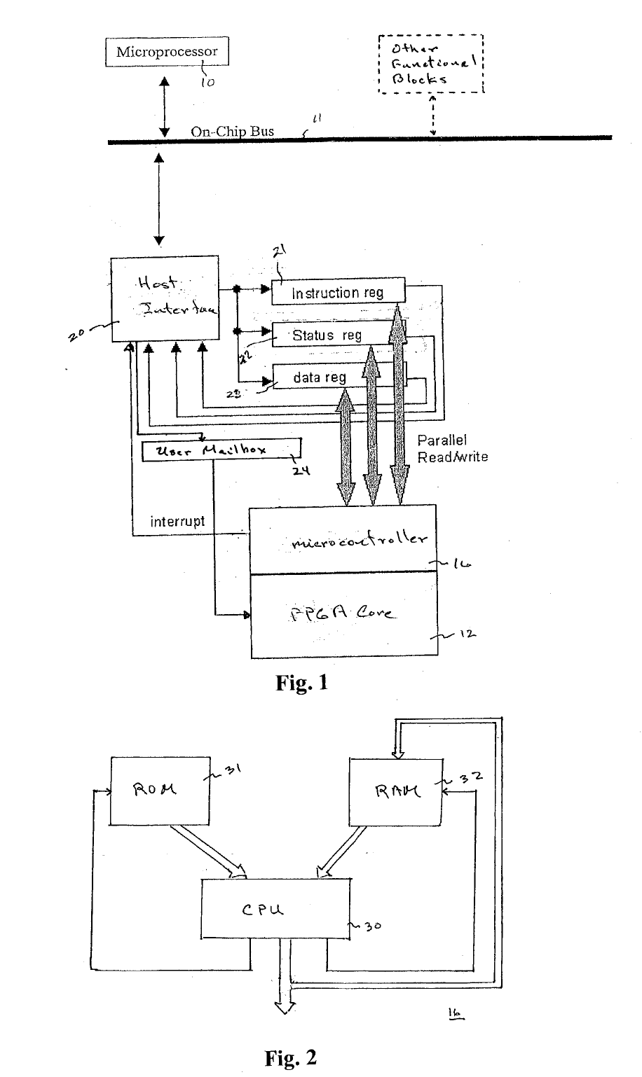

In one embodiment of the present invention, an ASIC is organized with a processor unit and embedded FPGA core, as shown in FIG. 1. Other functional blocks in the ASIC are not shown. The processor unit 10 communicates with other functional blocks through a bus 11. Among the functional blocks is an embedded FPGA core 12 which is connected to the bus 11 (and the processor unit 10) through a host interface 20, an interface between the rest of the ASIC and the FPGA core 12. The host interface 20 is adapted to handle the protocol for the particular bus 11, which may be a standardized bus, such as AMBA for the well-known ARM microcontrollers (which originate from ARM Ltd. of Cambridge, England), or a customized bus for a specialized processor unit.

The host interface 20 receive commands from the processor unit 10 and reissues equivalent commands to a microcontroller 16 to handle functions such as the loading of configuration bits for the FPGA core 12, monitoring of the configuration loading operations, self-testing of the FPGA core 12 by BIST (Built-In Self-Testing), monitoring of debugging operations. Connected between the host interface 20 and the microcontroller 16 is an instruction register 21, a status register 22, and a data register 23. Connected between the host interface 20 and the FPGA core 12 is a user mailbox register (or registers) 24 which hold information specific to the ASIC user and may be modified by the user.

The microcontroller 16 handles the configuration and testing of the FPGA core 12 upon instructions from the processor unit 10 through the bus 11 and host interface 20. Also, the microcontroller 16 can help debug the FPGA core 12, i.e., to service requests from software tools to debug errors in the FPGA core operation. The microcontroller 16 has a general instruction set that provides access to all resources within the FPGA core. This enables the microcontroller to provide higher level services such as configuration loading, configuration monitoring, built-in self test, defect analysis, and debugger support (which includes clock control, register reading and writing).

In accordance with the present invention, the host interface 20 is the unit which must be adapted to the requirements of the protocols of the bus 11 of each ASIC design. The FPGA core 12, the microcontroller 16, the instruction register 21 and the other elements beyond the host interface 20 can be installed into ASIC as a unit once the host interface 20 has been properly designed.

FPGA Core Microcontroller

The instructions and necessary data from host interface 20 are interpreted and executed by the microcontroller 16. In turn, the microcontroller 16 uses the interface 20 to communicate status and requested data back to the processor unit 10. Having received an instruction, the microcontroller 16 generates the low level control and data transfer sequences needed to perform the requested function. These functions include loading configuration data to the FPGA core 12, reading back and verifying the loaded data, examining and/or modifying the contents of FPGA registers, built-in self test (BIST) of the entire FPGA core 12, and various diagnostic functions relating to the microcontroller's memories. As illustrated in FIG. 2, the microcontroller has a CPU 30 and ROM (Read-Only Memory) 31 and RAM (Random Access Memory) 32, a Static RAM. The ROM 31 contains the firmware or microcode for the microcontroller 16 to perform its operations required by an instruction received through the interface 20.

For instance, after power-on reset, the microcontroller 16 installs a default configuration in the FPGA core 12 in one embodiment of the present invention. The microcontroller 16 then halts itself. An interrupt from the processor unit 10 through the host interface 20 brings the microcontroller 16 out of its halt state, and a configuration and/or BIST session can proceed. After configuration, a final HALT instruction is issued which returns the microcontroller 16 to its inactive state.

The microcontroller 16 is designed to handle these various operations flexibly and with ease. In the present embodiment of the present invention, a basic instruction format consists either of a single 16-bit instruction, or a 16-bit instruction plus a 16-bit immediate data extension.

In the Single Word Format:

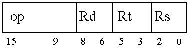

In the Double Word Format:

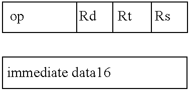

The register fields, Rd, Rt, and Rs are each 3 bits wide and are used primarily to select 2 source registers and a destination register for the instruction. For some instructions, not all 3 registers are needed, so the corresponding bit fields may be used for various instruction options. If a particular bit field is not used for register selection, the instruction listing will refer to the field as wd (instead of Rd), wt (instead of Rt), or ws (instead of Rs), as required, to improve clarity. Instructions that use immediate data interpret the 16-bit extension word in various ways.

For most instructions, the op field is 7 bits wide, and is decoded as follows.

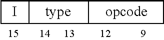

| | | |
|---|---|---|
| I | | Selects single word, or 2 word format |
| type | 00 | Logic / Arithmetic instructions -flags not set |
| | 01 | I/O instructions, process control |
| | 10 | Logic / Arithmetic instructions -flags set |
| | 11 | Branch |
| opcode | | 1 of 16 instruction codes. |

Some instructions may not strictly follow this decoding scheme. A list of exemplary instructions for the microcontroller 16 is found below in the Appendix at the end of this specification.

Details of FPGA Core

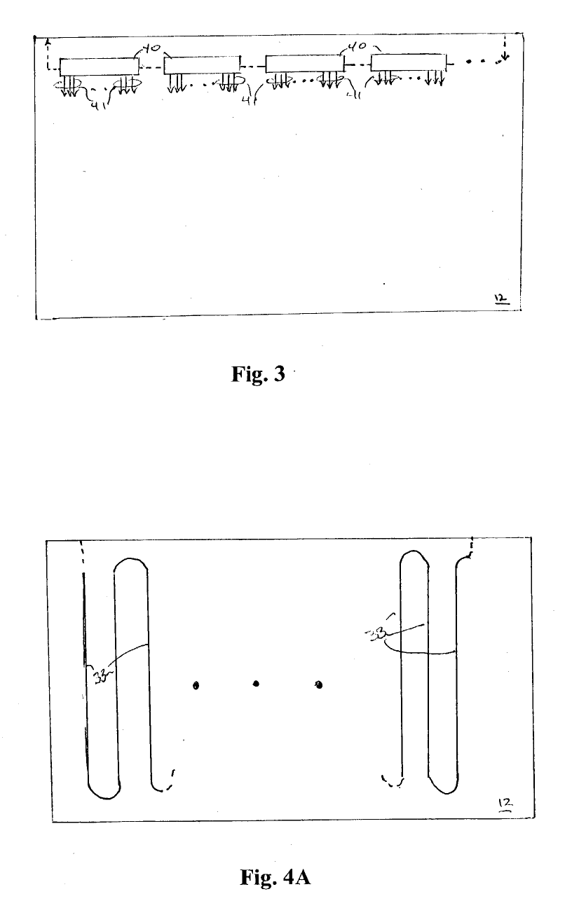

A typical FPGA core has banks of registers to hold the configuration bits which set the switches in the FPGA logic and interconnection paths of the core. These configuration bits are scanned into the registers to conserve wiring space. FIG. 3 indicates these configuration registers 40; the lines 41 emanating from these registers indicate the control lines to the switches (including multiplexers) in the core 12.

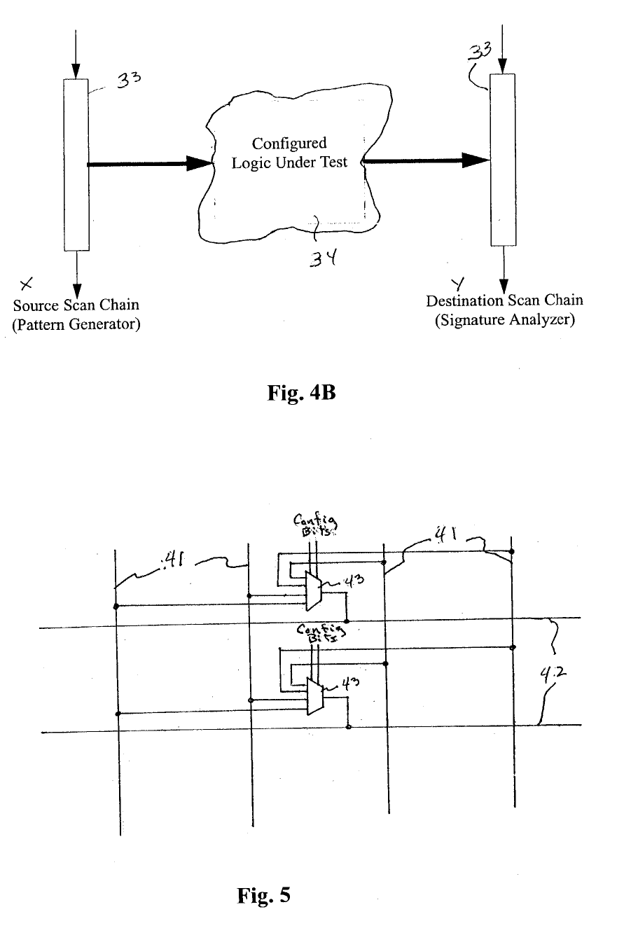

For purposes of testing a configured FPGA core 12 in accordance with the present invention, the core 12 also has scan strings 33, which are symbolically illustrated in FIG. 4A. Each string 33 is created from serially-connected registers and each register cell in a string is connected to a selected location in the core 12 to impress the binary value held by the cell to the selected location or receives a binary value from the location. These scan strings 33 are used for the BIST operations described in greater detail below. The scan strings 33 are distributed and connected in pairs to various locations in the core 12, as illustrated in FIG. 4B.

A section or portion of the FPGA core 12, i.e., the logic (FPGA core cell) and interconnections (routing path), is cut and bounded by the scan chains, here labeled X and Y. The pattern generator is one scan chain, arbitrarily labeled X, which drives the data patterns into the configured logic section 34 to be tested. The patterns may be arbitrary or determined for targeting specific features in the FPGA core 12 to be tested. The signature analyzer is a scan chain, here labeled Y, with the LFSR (Linear Feedback Shift Register)-mode enabled such that the logic response of the logic section 34 is combined with the scan chain data to create a signature value that is accumulated by the Y scan chain for a predetermined number of iterations. Multiple cuts of logic can be tested in this fashion by driving the signature accumulated from one cut of logic to another. Thus, a series of logic cuts can be tested simultaneously with X and Y scan chains alternating between stages.

As stated above, the scan chains 33 allow specific features of the FPGA core 12 to be tested. For a particular embodiment of the present invention, the FPGA core 12 has a multiplexer-based, hierarchical architecture which invites testing at different levels and of different features.

A small example of a multiplexer-based interconnect network is shown in FIG. 5 in which four vertical wires 41 intersect two horizontal wires 42. Rather than pass transistors or pass gates of a typical FPGA interconnect network, multiplexers 43 are used. In this example, each horizontal wire 42 is connected to the output terminal of a multiplexer 43 which has its input terminals connected to the vertical wires 42. Each horizontal wire 42 is driven by a 4:1 multiplexer 43 which is controlled by two control bits. In this simple example, only four configuration bits are required for the instead of eight in the case of the conventional configurable network implemented with pass transistors.

A multiplexer-based configurable interconnect network has many advantages over pass transistor configurable interconnect network typically found in FPGAs. The FPGA core 12 also has a hierarchical architecture with the multiplexer-based configurable interconnect network. A hierarchical architecture has the advantages of scalability. As the number of logic cells in the network grows, the interconnection demand grows super-linearly. In a hierarchical network, only the higher levels of the hierarchy need to expand and the lower levels remain the same. An interconnect architecture may be automatically generated and allows FPGA cores to be easily embedded. An automatic software generator allow the user to specify any size FPGA core. This implies the use of uniform building blocks with an algorithmic assembly process for arbitrary network sizes with predictable timing.

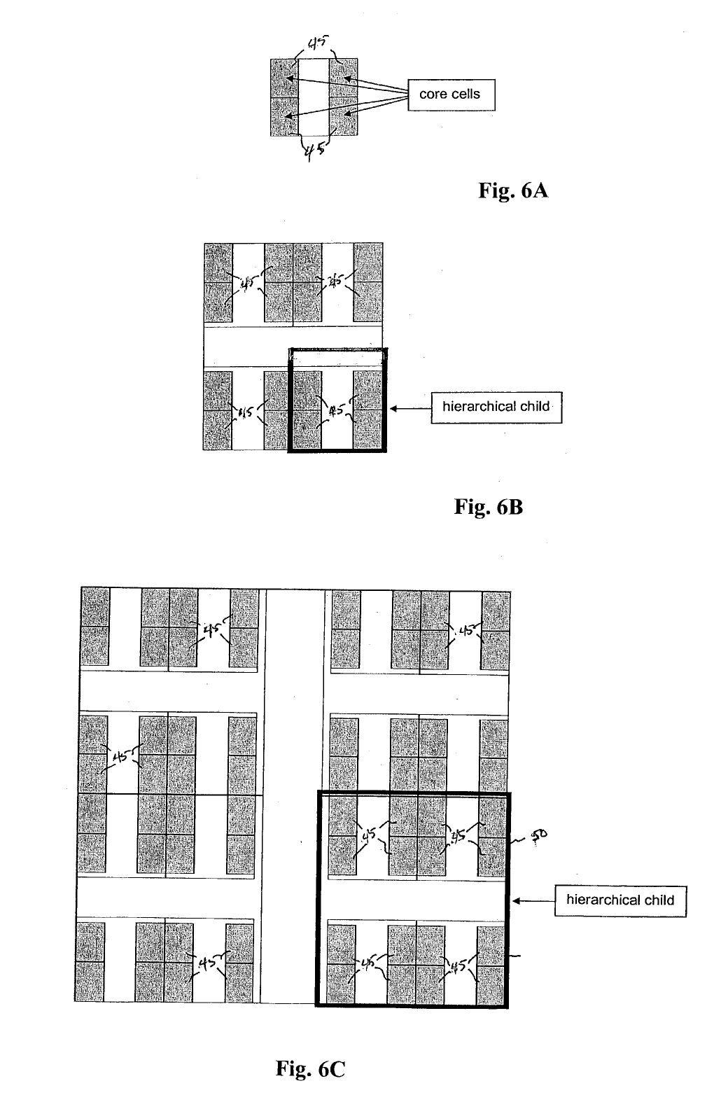

In the FPGA core 12, every level of the hierarchy is composed of 4 units, i.e., stated differently, every parent (unit of a higher level) is composed of four children (units of a lower level). The bottommost level is composed of 4 core cells, as illustrated in FIG. 6A. FIG. 6B shows how four bottom level units form a second hierarchy level unit and FIG. 6C shows how four second level hierarchy level units 50 form a third hierarchy level unit. Thus a third level unit is formed from 64 core cells. Of course, the number of children can be generalized and each level can have a different number of children in accordance with the present invention.

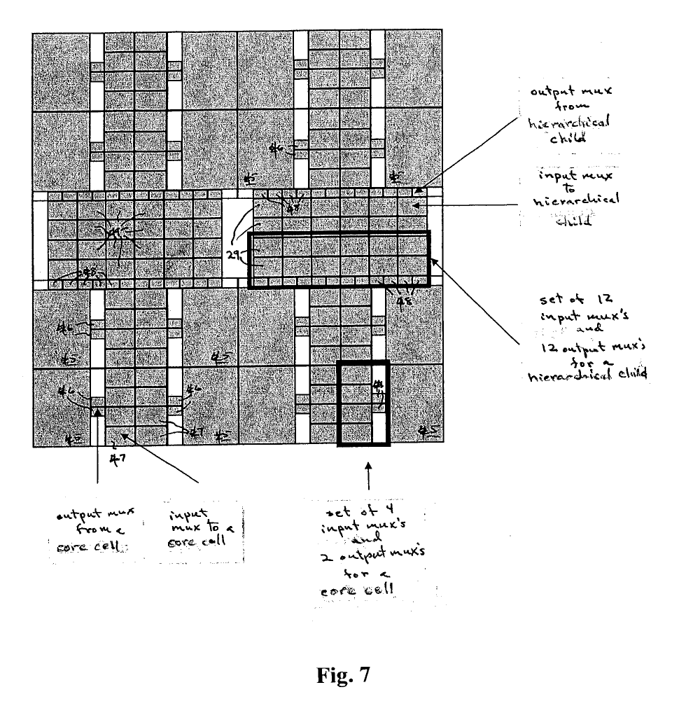

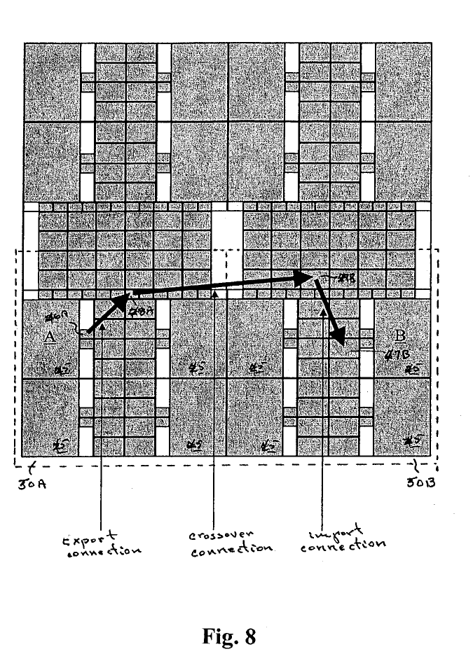

Every child at every level has a set of input multiplexers and a set of output multiplexers which provides input signal connections into the child unit and output signal connections out from the child, respectively. In the exemplary hierarchy shown in FIG. 7, a core cell 45 has four input multiplexers 46 and two output multiplexers 47, but the interconnect architecture can be generalized to any number of input multiplexers and output multiplexers. Four core cells 45 form a bottommost level which has a set of 12 input multiplexers 58 and 12 output multiplexers 49. Likewise, the next hierarchical level unit has a set of input multiplexers and a set of output multiplexers, and so on.

The pattern of connections for the multiplexers has three categories: export, crossover, import. These different categories are illustrated by FIG. 8 in an example connection route from a core cell A to a core cell B. There is an connection from an output multiplexer 46A of the core cell A to an output multiplexer 48A of the bottommost, hierarchical level 1, unit 50A holding the core cell A. Then there is a crossover connection from the output multiplexer 48A to an input multiplexer 49B of the level 1 unit 50B holding the core cell B. Units 50A and 50B are outlined by dotted lines. Finally, there is an import connection from the input multiplexer 49B to an input multiplexer 47B of the core cell B. It should be noted that the configured connections all lie within the lowest hierarchical level unit which contains both ends of the connection, i.e., the core cell A and core cell B. In this example, the lowest level unit is the level 2 unit which holds 16 core cells 25, including core cells A and B. The details of this FPGA interconnect architecture are beyond the scope of this invention. More details can be found in U.S. application Ser. No. 10/202,397, entitled, “Hierarchical Multiplexer-Based Integrated Circuit Interconnect Architecture For Scalability and Automatic Generation,” filed Jul. 24, 2002 by Dale Wong and John D. Tobey, and assigned to the present assignee.

In comparison to a mesh-type architecture, the multiplexer-based, hierarchical architecture of the FPGA core 12 invites testing of the different features of the core 12 in particular fashion. With the host interface 20 and microcontroller 16, such testing can be performed as described below.

Host Interface Commands for Configuration and BIST

To engage the microcontroller 16, commands from the microprocessor 10 are passed via the host interface 20 to the microcontroller instruction register 21. Many instructions also require some additional information, such as an address, or write data. If needed, this is scanned into the data port register 23 prior to loading the instruction register 21. Loading the instruction register 21 causes the microcontroller 16 to be interrupted. On interrupt, the microcontroller 16 reads the instruction register 21, decodes the instruction, reads the data port register 23 if the instruction requires it, and goes on to perform the required command. While commands are being processed, the controller 16 does not respond to further interrupts; rather, the interrupt is latched and become active when the current command terminates.

Immediately after loading the instruction register 31, the host interface 20 starts polling the status register 22. It is assumed that the command is in progress until a non-zero code is detected in the status register 22. All valid status codes return a “1” in the lsb (least significant bit) position of the register 22. If the rest of the register is 0, the controller is unable to perform the command for which there may be several reasons for such a response. The command code could be invalid; some commands must follow in a particular order; or the address or data may be out of range. If the instruction completed successfully, bit [1] of the status register 22 is also be set. Some instructions result in data being supplied by the microcontroller 16 to the microprocessor unit 10 through the host interface 20. When the successful completion code is detected, the microprocessor 10 can then proceed and read the data register 23 to obtain this information.

After power-on reset, or any time after the HALT command is issued, the instruction register 21 is in a locked state. That is, it will not respond to commands; all except a Verify_Security_Key command is rejected. A valid 32-bit security code must be presented to the data register 23 before access to the general set of commands is granted.

The following is a list of exemplary commands available to the microprocessor unit 10 for the FPGA configuration operations.

| | |
|---|---|
| Start_Configuration | Code = 1 |

This command is to be issued before any of the configuration load or readback commands (see codes 2-8 below). Start_Configuration unlocks those commands and makes them available. When configuration loading is completed, the End_Configuration command (code=10), should be issued to relock these commands and prevent inadvertent modification of the configuration. Command codes other than code=2 through 8, are available at all times once the security key is verified.

| | | |
|---|---|---|
| return | 3 | OK |
| | 1 | Instruction rejected |

| | |
|---|---|
| Start_Sequential_Load | Code=2 |

Issued to begin a sequential configuration load sequence. This first part of the sequence specifies the starting address in the FPGA where configuration data is to be stored. This address should be placed in the data register 23.

FPGA addresses are a 3-tuple comprised of a row number, a column number, and a quadrant number. They are encoded into a 32-bit word as follows:

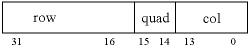

Return codes for this instruction are:

| | | |
|---|---|---|
| return | 3 | Ready for data |

| | |
|---|---|
| 1 | Instruction rejected |

| | |
|---|---|
| Load_Sequential_Data | Code = 3 |

Follows after a code=2 instruction. This instruction completes the sequential write sequence by providing the data to be loaded. The data should be placed in the data register 23. After the load, the load address is auto-incremented (by column). Code=3 instructions may be issued repeatedly, until the desired load address is no longer sequential.

| | | |
|---|---|---|
| return | 3 | Load completed |

| | |
|---|---|
| 1 | Instruction rejected |

| | |
|---|---|
| Start_Parallel_Load | Code = 4 |

This command is issued to begin a parallel load sequence. The data to be parallel loaded is provided in this instruction, and should be placed in the data register 23. The parallel load facility simultaneously loads a single data item across multiple locations in a single write cycle, which can result in significant improvement in configuration load time.

| | | |
|---|---|---|
| return | 3 | OK |

| | |
|---|---|
| 1 | Instruction rejected |

| | |
|---|---|
| Parallel_Load_Start_Address | Code = 5 |

This command is issued after a code=4 instruction to specify the starting address where the specified data word is to be loaded. The address should be placed in the data register 23.

| | | |
|---|---|---|
| return | 3 | Ready for ending address |

| | |
|---|---|
| 1 | Instruction rejected |

| | |
|---|---|
| Parallel_Load_Ending_Address | Code = 6 |

This command is issued after a code=5 instruction to complete the parallel load. The ending address should be placed in the data register 23. The specified data word is parallel loaded to sequential locations in the FPGA core 12 beginning with the start address, and terminating with the end address, inclusive. This is a single-cycle write. Addresses may be sequential by either row or column. The order is detected automatically, according to which portion of the address is different. It is immaterial whether the ending address is higher or lower than the start address. Both the start, the end, and all locations in-between are loaded. If the start and end addresses are the same, only that one location is loaded.

| | | |
|---|---|---|
| return | 3 | Load completed |

| | |
|---|---|
| 1 | Instruction rejected |

| | |
|---|---|
| Start_Sequential_Read_of_Configuration_Data | Code = 7 |

This command is issued to begin a sequential configuration read sequence. The starting address of the read cycle should be placed in the data register 23. This instruction reads the first data item from the FPGA core 12, replacing the contents of the data register 23.

| | | |
|---|---|---|
| return | 3 | OK |

| | |
|---|---|
| 1 | Instruction rejected |

| | |
|---|---|
| Read_Sequential_Configuration_Data | Code = 8 |

This instruction reads additional sequential configuration data items after a code=7, without having to scan in a new address. The previous address is auto-incremented (by columns) after every read. This instruction may repeat as many times as desired. Data items are placed in the data register 2.

| | | |
|---|---|---|
| return | 3 | Load completed |

| | |
|---|---|
| 1 | Instruction rejected |

| | |
|---|---|
| Verify_Security_Key | Code = 9 |

This must be the first instruction issued before any other configuration command is accepted. The security key (a 32-bit pre-assigned integer) must be placed in the data register 23. The microcontroller 16 reads the value and compares it to an internally held copy of the key. If they match, full access is allowed. If the match fails, access is restricted to code=9 instructions only.

| | | |
|---|---|---|
| return | 3 | OK |

| | |
|---|---|
| 1 | bad key |

| | |
|---|---|
| End_Configuration | Code = 10 |

This instruction terminates a configuration load/read session, and locks out instructions with code=2 through 8. All other instructions remain active.

| | | |
|---|---|---|
| return | 3 | OK |

| | |
|---|---|
| 1 | Instruction rejected |

| | |
|---|---|
| Read_Bundle_X_Register | Code = 11 |

The desired bundle number (in the range 0-63) is placed in the data register 23 and this instruction causes the X-scan chain to be internally scanned by the microcontroller 16 until the data from the desired 16-bit bundle register appears. The bundle register is read out, and copied to the data register 23. Then the scan chain is further shifted in a circular manner until the entire scan chain has been restored back to its original state.

| | | |
|---|---|---|
| return | 3 | Register data ready |
| | 1 | Instruction rejected |
| Read_Bundle_Y_Register | | Code = 12 |

The desired bundle number (in the range 0-63) is placed in the data register 23 and this instruction causes the y-scan chain to be internally scanned by the microcontroller 16 until the data from the desired 16-bit bundle register appears. The bundle register is read out, and copied to the configuration loader data register 33. Then the scan chain is further shifted in a circular manner until the entire scan chain has been restored back to its original state.

| | | |
|---|---|---|
| return | 3 | Register data ready |
| | 1 | Instruction rejected |
| Write_Bundle_X_Register | | Code = 13 |

This instruction initiates a write sequence to a particular bundle X-register. The bundle number is placed in the data register 23. A following code=14 instruction provides the data for the write operation.

| | | |
|---|---|---|
| return | 3 | OK, ready for data |
| | 1 | Instruction rejected |
| Write_Bundle_Register_Data | | Code = 14 |

This instruction follows either a code=13 instruction, or a code=15 instruction. It provides the data for the bundle register write operation. Writing proceeds similarly to how the bundle register read operations work. The X or Y scan chain is scanned until the data from the desired register appears. In this case, rather than reading the register, it is replaced. Then the scanning continue until the scan chain is restored to its original state (except for the new register value).

| | | |
|---|---|---|
| return | 3 | Write operation completed |
| | 1 | Instruction rejected |
| Write_Bundle_Y_Register | | Code = 15 |

This instruction initiates a write sequence to a particular bundle Y-register. The bundle number is placed in the configuration loader data register. A following code=14 instruction provides the data for the write operation.

| | | |
|---|---|---|
| return | 3 | OK, ready for data |
| | 1 | Instruction rejected |
| Shift_X_Scan_Chain | | Code = 16 |

This is a lower level function that shifts the X scan chain by an arbitrary number of bits from 1 to 32. The bit count should be placed in the data register 23. The shift occurs when a following instruction (code=17) supplies the scan-in data pattern.

| | | |
|---|---|---|
| return | 3 | OK, ready for scan-in pattern |
| | 1 | Instruction rejected |
| Shift_Scan_Data | | Code = 17 |

This instruction follows either a code=16 or a code=18 instruction and supplies the data pattern to scan in when the shift occurs. The data register 23 becomes part of the scan chain when shifting occurs, so as data is shifted out of the register at the lsb (least significant bit) end, the scan-out data from the scan chain is shifted in on the msb (most significant bit) end. When the instruction is complete, the microprocessor 10 may recover the data which was scanned out.

| | | |
|---|---|---|
| return | 3 | Shift operation completed |
| | 1 | Instruction rejected |
| Shift_Y_Scan_Chain | | Code = 18 |

This is a lower level function that shifts the scan chain by an arbitrary number of bits from 1 to 32. The bit count is placed in the data register 23. The shift occurs when a following instruction (code=17) supplies the scan-in data pattern.

| | | |
|---|---|---|
| return | 3 | OK, ready for sean-in pattern |
| | 1 | Instruction rejected |
| Reload_Default_Configuration | | Code = 19 |

On power-on startup, the configuration loader 21 installs a default configuration into the FPGA core 12. This configuration can be reloaded at any time by issuing this instruction.

| | | |
|---|---|---|
| return | 3 | Configuration loaded. |
| | 1 | Instruction rejected |
| Begin_Download_to_Code_RAM | | Code = 20 |

This instruction sets up a download sequence for the microcontroller's microcode. The starting address (in microcontroller code space) for the download is to be placed in the configuration loader data register 33.

| | | |
|---|---|---|
| return | 3 | OK, ready for data |
| | 1 | Instruction rejected |
| Download_Code | | Code = 21 |

This instruction follows a code=20 instruction. The data word to download next is placed in the data register 23. The microcontroller 16 actually uses 16-bit instructions, whereas the data register 23 is 32 bits wide, so this instruction really downloads a pair of instructions. On completion, the address is auto-incremented appropriately. This instruction may repeat indefinitely until a non-sequential address is required.

| | | |
|---|---|---|
| return | 3 | Data loaded |

| | |
|---|---|
| 1 | Instruction rejected |

| | |
|---|---|
| Read_R16_Code | Code = 22 |

This instruction is used to read the microcontroller code either from its ROM or from its code RAM. The desired microcontroller memory address should be placed in the data register 23 and the code at that location is read, and it replaces the previous contents of the data register 23.

| | | |
|---|---|---|
| return | 3 | Data ready |

| | |
|---|---|
| 1 | Instruction rejected |

| | |
|---|---|
| Read_Sequential_R16_Code | Code = 23 |

This instructions follows a code=22 instruction. It allows additional sequential code words to be read without having to scan in a new address. The location after the last read code word, is read and put into the configuration loader data register 23. Then the address is appropriately auto-incremented. This instruction may be repeated indefinitely.

| | | |
|---|---|---|
| return | 3 | Data ready |

| | |
|---|---|
| 1 | Instruction rejected |

| | |
|---|---|
| Do_BIST | Code = 24 |

This instruction causes the BIST routines to be run in sequence. BIST stops on the first failure, and reports its results. If there are no failures, testing continues until all tests have been run. A predefined 4-word block of data in the 32-bit data RAM of the microcontroller 16 then holds a summary of the test results in the following format:

| | |
|---|---|
| blk_addr | 0=> pass −1 =>fail |
| blk_addr + 1 | Test number |
| blk_addr + 2 | Failing position in scan chain |
| blk_addr + 3 | Actual signature read |

The only test reported is the final test. This would be the failing test if a failure is detected. The position in the scan chain is an indicator (down to the bundle level), along with the test number (since that indicates what structure is being tested), of where in the FPGA core 12 the fault is. If the test passes, the test number is the final test, position in the scan chain is the end of the chain, and actual signature is the correct signature.

This test block should be examined by the microprocessor unit 10 by issuing Read_Data_RAM instructions (code=28 and 29).

For BIST, the status return gives a quick indication of pass or fail.

| | | |
|---|---|---|
| return | 7 | BIST passed |

| | |
|---|---|
| 3 | BIST failed |
| 1 | Instruction rejected |

| | |
|---|---|
| Do_BIST_N | Code = 25 |

This instruction is similar to code=24, except that only a single BIST test is run. The test number should be placed in the configuration loader data register 33. The single test returns in the same manner as for code=24:

| | | |
|---|---|---|
| return | 7 | BIST passed |

| | |
|---|---|
| 3 | BIST failed |
| 1 | Instruction rejected |

| | |
|---|---|
| Write_DATA_RAM_ADDR | Code = 26 |

Issued to initiate a write sequence to the 32-bit data RAM of the microcontroller 16. This instruction supplies the starting address for a possible sequence of consecutive writes. The address (in the microcontroller data RAM space) is placed in the data register 23.

| | | |
|---|---|---|
| return | 3 | OK, ready for data |

| | |
|---|---|
| 1 | Instruction rejected |

| | |
|---|---|
| Write_DATA_RAM | Code = 27 |

This instruction follows a code=26 instruction. The data to be written is placed in the data register 23. It is written to the specified address, and then the address is auto-incremented for the next write. This instruction may be repeated indefinitely as long as the desired write address remains sequential.

| | | |
|---|---|---|
| return | 3 | Write completed |

| | |
|---|---|
| 1 | Instruction rejected |

| | |
|---|---|
| Read_DATA_RAM_Addr | Code = 28 |

This instruction initiates a data RAM read sequence to the 32-bit data RAM of the microcontroller 16. The address is supplied in the data register 23. Data at this address is read, which then replaces the previous contents of the data register 23.

| | | |
|---|---|---|
| return | 3 | Data ready |

| | |
|---|---|
| 1 | Instruction rejected |

| | |
|---|---|
| Read_DATA_RAM | Code = 29 |

Issued after a code=28 instruction. This instruction does sequential data RAM reads without having to scan in a new address. The data is read form the memory location following the previously read location, and then the address is auto-incremented. This instruction can be repeated indefinitely, as long as the desired address is sequential.

| | | |
|---|---|---|
| return | 3 | Data ready |

| | |
|---|---|
| 1 | Instruction rejected |

| | |
|---|---|
| Execute_Subroutine | Code = 30 |

This instruction is issued to cause the microcontroller 16 to branch to another location, possibly to execute downloaded code. There is the normal return code, but only if the executing subroutine returns to the calling program.

| | | |
|---|---|---|
| return | 3 | (if the subroutine returns) |

| | |
|---|---|
| 1 | Instruction rejected |

| | |
|---|---|
| Halt | Code = 31 |

This instruction shuts down the configuration loading operations. The operation of the microcontroller 16 is halted, and further program execution terminates. In the halted state, the microcontroller still responds to the certain interrupts, so configure loading activity can be resumed at a later time, but it then requires re-verification of the security key. Any configuration loaded prior to the halt remains intact.

return 3

BIST Operations

After the FPGA core 12 has been configured, it is prudent to test the integrity of the core. The microcontroller 16 implements a thorough and effective Built-In Self-Test of the FPGA core 12. The BIST routine performs an exhaustive test of every flip-flop and every interconnect path in the core 12. The BIST algorithms exercise the FPGA core 12 at various levels.

The present invention provides for a set of firmware routines called from the processor unit 10 or possibly from an host external to the ASIC. The firmware is located in the ROM of the microcontroller 16. Each routine targets an aspect of the FPGA core 12. The routines may be called individually, or all at once for a complete test of the FPGA core 12. The microcontroller controller 16 manages the execution of the BIST algorithms and the interpretation of the test results.

In this embodiment, there are 14 BIST routines which exist as subroutines in the microcontroller 16 interrupt handler in the firmware. Each BIST routine focuses on one aspect of the FPGA core 12. The BIST routines are also dependent upon each other in a hierarchical fashion. For example, tests which focus on the higher-level routing depend on the correct functionality at the lower levels of the core 12.

Each BIST algorithm has the following steps:

In step 1, the processor unit 10 issues a command to invoke either a single BIST algorithm or all algorithms.

In step 2, upon receipt of the command, the logic at the host port registers the command in the command register and the BIST test number, if any, in the data register.

An interrupt to the microcontroller 16 is triggered in step 3. The microcontroller 16 breaks out of a loop and begins servicing the interrupt.

The microcontroller 16 reads the command in step 4 and decodes it to determine if it is a BIST command. If the decoding is true, the microcontroller 16 reads the BIST test number and branches to the appropriate BIST routine.

In the BIST routine, the registers from which the test vectors are taken are placed in scan mode in step 5. Both the X and Y scan chains 43 are initialized with data.

In step 6, the FPGA core 12 is configured to set up a logic path between the X and Y scan chains. One scan chain acts a pattern generator which drives the logic to be tested. The other scan chain receives the results from the logic and accumulates them in an LFSR (Linear Feedback Shift Register).

The scan chains 43 are clocked a finite number of cycles in step 7.

In step 8, the actual signature at the destination scan chain is compared against the expected signature.

The results of the BIST routine are saved in the SRAM of the microcontroller 16 by step 9.

For BIST reporting, the status is reported as either passed or failed in a single BIST test. The return code is read by the processor unit 10 or the possible external host from the status register 22. Table 1 shows the meanings of the each possible return from a single BIST test.

TABLE 1
Single BIST Return Codes

| Return Code | Meaning |
|---|---|
| 7 | BIST test passed |
| 3 | BIST test failed. |
| 1 | BIST test command rejected. No. |
| | BIST test run. |

For a full BIST test, the status is reported exactly the same way as for a single BIST test. In addition, diagnostic information is stored in a reserved block of memory in the SRAM of the microcontroller 16. This block is a four 32-bit words with a base address of 0x20. Table 2 shows the map for the BIST diagnostic memory block. The information in the memory block can be read by the processor unit 10 with the Read_DATA_RAM_Addr and Read_DATA_RAM commands.

| RAM Address | Information |
|---|---|
| 0x20 | 0: Full BIST passed. |
| | −1: Full BIST failed. |
| 0x21 | Test number of last BIST routine |
| | executed. |
| 0x22 | Scan chain position (0-1023) where |
| | failure occurred. |
| 0x23 | Actual Signature. |

### Table 2 Full BIST Diagnostics Memory Map

Table 3 below lists the BIST tests which are included in the microcontroller 16 firmware. For each test, a feature is targeted and is swept by reconfiguration until all possible routes are covered.

TABLE 3
List of BIST Tests

| Test | |
|---|---|
| Number | Description of Test |
| 1 | Core cell LUT (Look Up Table) test. |
| 2 | Core cell input multiplexer test. Tests Vss and direction |
| | connection from X outputs. |
| 3 | Core cell input multiplexer test. Tests Vss and direction |
| | connection from Y outputs |
| 4 | Quad input multiplexer test. Tests the following path: x_reg-> |
| | quadoutmux->quadinmux->corecellmux->y_reg |
| 5 | Quad input multiplexer test. Tests the following path: y_reg-> |
| | quadoutmux->quadinmux->corecellmux->x_reg |
| 6 | Quad input multiplexer direct connection test. Tests the |
| | following path: : x_reg->quadoutmux->quadinmux-> |
| | corecellmux->y_reg |
| 7 | Bundle output multiplexer test. Tests the following path: |
| | x_reg->quadoutputmux->bundleoutmux->bundleinmux-> |
| | quadinputmux->corecellmux->y_reg |
| 8 | Quad hierarchical inputs test. Tests the following path: x_reg-> |
| | quadoutmux->bundleoutmux->bundleinmux->quadinmux-> |
| | corecellmux->y_reg |
| 9 | Bundle inut multiplexer direct connection test. Tests the |
| | following path: x_reg->quadoutmux->bundleoutmux-> |
| | bundleinmux->quadinmux->corecellmux->y_reg |
| 10 | Stripe output multiplexer test. Tests the following path: |
| | x_reg->quadoutmux->bundleoutmux->stripeoutmux-> |
| | stripeinmux->bundleinmux->quadinmux->corecellmux-> |
| | y_reg |
| 11 | Stripe input multiplexer direct connection test. Tests the |
| | following path: x_reg->quadoutmux->bundleoutmux-> |
| | stripeoutmux->stripeinmux->bundleinmux->quadinmux-> |
| | corecellmux->y_reg |
| 12 | Block output multiplexer test. Tests the following path: |
| | x_reg->quadoutmux->bundleoutmux->stripeoutmux-> |
| | blockoutmux->blockinmux->stripeinmux->bundleinmux-> |
| | quadinmux->corecellmux->y_reg |
| 13 | Stripe hierarchical inputs test. Tests the following path: |
| | x_reg->quadoutmux->bundleoutmux->stripeoutmux-> |
| | blockoutmux->blockinmux->stripeinmux->bundleinmux-> |
| | quadinmux->corecellmux->y_reg |
| 14 | Block input multiplexer test. Tests the following path: x_reg-> |
| | quadoutmux->bundleoutmux->stripeoutmux->blockoutmux-> |
| | blockinmux->stripeinmux->bundleinmux->quadinmux-> |
| | corecellmux->y_reg |

These particular BIST tests reflect the particular architecture of the FPGA core 12. In this architecture, besides being multiplexer-based and arranged in a hierarchy, the basic unit of the FPGA core, the core cell, is created by LUTs (Look-Up Tables) with two outputs, termed x and y. The present invention permits the special features of an FPGA core to be tested specifically and in a particular order for a complete test.

It should be noted that while the host interface 20 and the other elements associated with the FPGA core 12 permit the processor unit 10 to direct the configuration and BIST operations of the core 12, the bus 11 might be designed for connection to an external host to control configuration and BIST operations. Another alternative might be a port connected to the host interface 20 by which control of configuration and BIST operations might be directed.

While the foregoing is a complete description of the embodiments of the invention, it should be evident that various modifications, alternatives and equivalents may be made and used. Accordingly, the above description should not be taken as limiting the scope of the invention which is defined by the metes and bounds of the appended claims.

### Appendix—Instruction Set for Microcontoller

The basic instruction format consists either of a single 16-bit instruction, or a 16-bit instruction plus a 16-bit immediate data extension.

Single Word Format

Double Word Format

The register fields, Rd, Rt, and Rs are each 3 bits wide and are used primarily to select 2 source registers and a destination register for the instruction. For some instructions, not all 3 registers are needed, so the corresponding bit fields may be used for various instruction options. If a particular bit field is not used for register selection, the instruction listing will refer to the field as wd (instead of Rd), wt (instead of Rt), or ws (instead of Rs), as required, to improve clarity.

Instructions that use immediate data, will interpret the 16-bit extension word in various ways. The instruction listing provides details.

For most instructions, the op field is 7 bits wide, and is decoded as follows.

| I | | Selects single word, or 2 word format |
|---|---|---|
| type | 00 | Logic/Arithmetic instructions-flags not set |
| | 02 | I/O instructions, process control |
| | 12 | Logic/Arithmetic instructions-flags set |
| | 13 | Branch |

| | |
|---|---|
| opcode | 1 of 16 instruction codes. |

Some instructions may not strictly follow this decoding scheme. Details are provided in the instruction listing.

Processor Status

The Processor Status Register contains the following status bits

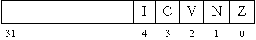

| | |
|---|---|
| I | Interrupt Enable |
| Z | Result is zero. |
| N | Result is negative. |
| V | Arithmetic result caused overflow. |
| C | Carry-out / carry-in bit. |

The Processor Status Register (PSR), is known as an extended register. Extended registers are register that have very specific dedicated functions and must be referenced indirectly through special MOV instructions that can copy them to and from normal data registers.

Extended Register Index

| Code | Mnemonic | Description |
|---|---|---|
| 0 | PSR | Processor Status |
| 1 | IADDR | Interrupt Routine Address |
| 2 | IRETURN | Interrupt Return Address |
| 3 | IPSR | Saved PSR of Interrupted Routine |

Interrupts

The interrupt system is enabled by setting the I-bit in the PSR. On startup, the I-bit, is set to zero.

If interrupts are enabled, an interrupt is initiated when a logic one is asserted on the rat16 INTR pin. This pin is level sensitive, so the logic one level must be asserted until the interrupt is accepted. Acceptance is acknowledged when the cpu asserts a logic one on the IACK pin. IACK will remain active until INTR is de-asserted. INTR may be asserted for another interrupt only when IACK returns to a logic zero.

When an interrupt request has been recognized by the cpu, but not yet taken, the cpu begins looking for an instruction boundary that it can use to force the interrupt. There are some restrictions. Double word instructions cannot be interrupted until the second word has been fetched. An interrupt cannot be taken if a branch or jump instruction that can potentially change the program flow is still in the pipeline. An interrupt cannot be taken if the instruction fetcher is stalled, as, for instance, if a code space data read is occurring. Accordingly, interrupt latency is unpredictable.

When a suitable instruction boundary is reached, the instruction decoder jams a jump instruction into the pipeline. The target of the jump is the address currently in the iaddr register. The current PC is saved in ireturn, and the current PSR is saved in ipsr. PSR then has its I-bit set to zero, disabling further interrupts.

iaddr should be the address of an interrupt handler. When the interrupt processing is completed, the handler should return by restoring ipsr to PSR, and then performing a jump to ireturn.

IACK is asserted when the interrupt is taken.

Move Register

MOV

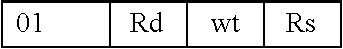

| Move reg Rs, into register Rd. | |
|---|---|
| 41 | Move #datal6 into upper or lower half of Rd |

| | |
|---|---|
| wt[0] | --reserved— |
| wt[2:1] | 00: move to lower Rd. Upper Rd is sign extended. |
| | 01: move to lower Rd. Upper Rd is set to zero. |
| | 10: move to upper Rd. Lower Rd remains unchanged. |
| | 11: move to upper Rd. Lower Rd is set to zero. |

Assembler Syntax

| | | |
|---|---|---|
| mov | r4, r3 | copy r3 into r4 |
| mov | r4, # 0xffff | sign extend the 16 bit quantity 0xffff and put in r4 |
| mov1 | r4, #27 | clear r4, then put (decimal) 27 into the lower half |
| movu | r4, #8 | clear r4, then put 8 in the upper half |
| movu16 | r4, #8 | put 8 in the upper half of r4, leave lower half |
| | | unchanged |

Bitwise Complement Register

NOT

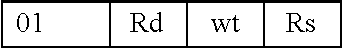

| | |
|---|---|
| 01 | Not reg Rs, into register Rd. |

| | |
|---|---|
| wt[2:0] | 010: move complement of Rs to Rd. |

NOT is a special case of the MOV instruction.

Move Extended Register to Register File

MOV

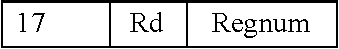

| | |
|---|---|
| 17 | Move extended register Regnum, into register Rd. |

Move Register File Register to Extended Register

MOV

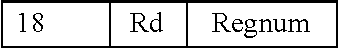

| | |
|---|---|
| 18 | Move register Rd, into extended register Regnum. |

Note: see extended register list on page 2 for extended register codes and mnemonics.

Load Register

LDR

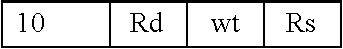

| | |
|---|---|
| 10 | Rd is loaded with the contents of progmem[Rs] |
| 11 | Rd is loaded with the contents of datamem[Rs] |
| 12 | Rd is loaded with the contents of configmem[Rs] |
| 50 | Rd is loaded with the contents of progmem[Rs+ data16] |
| 51 | Rd is loaded with the contents of datamem[Rs+ data16] |
| 52 | Rd is loaded with the contents of cotfigmem[Rs+ data16] |

| | |
|---|---|
| wt[0] | 0: Rs remains unchanged. |
| | 1: Rs is post incremented by 1. |

Following has meaning if the target is progmem only

| | |
|---|---|
| wt[2:1] | 00: load 16 bits to lower Rd. Upper Rd is sign extended. |
| | 01: load 16 bits to lower Rd. Upper Rd is set to zero. |
| | 10: load 16 bits to upper Rd. Lower Rd is unchanged. |
| | 11: load 16 bits to upper Rd. Lower Rd is set to zero. |

If the target is datamem or configmem, wt has the following additional meaning.

| | |
|---|---|
| wt[2:0] | 011: Rs is pre-decremented by 1. |

Assembler Syntax for LDR instruction

| | |
|---|---|
| ldr prog r3,[r5] | load r3 with sign extended 16 bit rom data at |
| | rom[r5] |
| ldr prog r3,[r5++] | load r3 with sign extended 16 bit rom data at |
| | rom[r5]. |
| | Then increment r5. |
| ldrl prog r3,[r5,0x100] | Clear r3, then load the lower half with 16 |
| | bit rom data at rom[r5+0x100] |
| ldru prog r3,[r5++,0x100] | Clear r3, then load the upper half with 16 bit |
| | rom data at rom[r5+0x100], |
| | then increment r5. |
| ldru16 prog r3,[r5] | Load the upper half of r3 with 16 bit rom |
| | data at rom[r5],the lower half of r3 retains |
| | its previous value. |
| ldr r3,[r5] | load r3 with 32 bit sram data at sram[r5] |
| ldr data r3,[I−−r5] | r5=r5−1, then load r3 with 32 bit data at |
| | sram[r5] |
| ldr r3,[r5++] | post increment r5 |
| ldr r3,[r5++,apple] | load r3 with the array element apple[r5] in |
| | sram, then increment r5. |
| ldr config r3,[r5] | The lower half of r5 contains a row number. |
| | The upper half of r5 contains a column |
| | number. |
| | Load r3 with the configuration data at |
| | config {col,row}. |

Store Register

STR

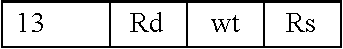

| | |
|---|---|
| 13 | The contents of register Rd are stored in datarnem[Rs] |
| 14 | The contents of register Rd are stored in configmem[Rs] |
| 19 | The upper or lower half of Rd is stored in progmem[Rs] |
| 53 | The contents of register Rd are stored in datamem[Rs + data16] |
| 54 | The contents of register Rd are stored in configmem[Rs + data16] |
| 59 | The upper or lower half of Rd is stored in progmem[Rs + data16] |

| | |
|---|---|
| wt[1:0] | 00: reg Rs is not changed. |
| | 01: reg Rs is post incremented. |
| | 11: reg Rs is pre-decremented. |

The following meaning for wt[2] applies only if the target memory is progmem.

| | |
|---|---|
| wt[2] | 0: lower half of Rd is stored |
| | 1: upper half of Rd is stored |

The following meaning for wt[2:0] applies only if the target is configmem.

| | |
|---|---|
| wt[0] | 0: reg Rs is not changed |
| | 1: reg Rs is post incremented (pre-decrement is not available) |
| wr[2:1] | 00: the config decoder is loaded with a starting address, but no |
| | config store cycle takes place. |
| | 01: (default) the config decoder is loaded with a starting address |
| | and the store cycle is executed. |
| | 11: the config loader is loaded with an ending address, and all |
| | config locations from the starting address to the ending |
| | address receive the Rd data simultaneously. |

Assembler Syntax for STR instruction

| | |
|---|---|
| strl prog r3,[r5] | Store r3[15:0] at program memory[r5] |
| stru prog r3,[−−r5] | r5=r5−1, then store r3[31:16] at program ram[r5] |
| str r3,[r5] | store r3 at sram location sram[r5] |
| str data r3,[r5] | --same as above--- |
| str r3,[r5++] | post increment r5 |
| str r3,[r5++,apple] | store r3 in the array element apple[r5] in sram, |
| | then increment r5. |
| str config r3,[r5] | The lower half of r5 contains a row number. |
| | The upper half of r5 contains a column number. |
| | Store r3 in the configuration data location |
| | config{col,row}. |
| str,p1 config r3,[r5] | Initialize decoder with starting address. |
| str,p2 config r3,[r6] | Store r3 in locations, R5 to R6 inclusive |

SCAN

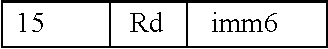

| | |
|---|---|
| 15 | Scan X |
| 16 | Scan Y |

The scan instruction halts the machine for imm6 cycles. While halted, either output signal scan_x or scan_y, is asserted. Serial-out data is shifted out of the LSB of Rd, and serial-in data is shifted into the MSB of Rd.

Assembler Syntax

scanx r4,#32

scany r4,#3

Jump

JMP

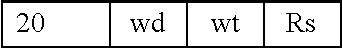

| | |
|---|---|
| 20 | The program counter is loaded with Rs. |
| wd | reserved |
| wt | reserved |

This instruction is typically used to return from a subroutine, where Rs contains the return address.

Assembler Syntax

jump r6

ADD

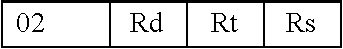

| | |
|---|---|
| 01 | Rd = Rt + Rs |
| 42 | Rd = Rt + data16 |

Assembler Syntax

| | |
|---|---|
| add | r4,r4,r3 |
| add | r2,rl,#6 |
| add,s | r2,r3,r5 ;set c,n,z,v |

ADD with Carry

ADDC

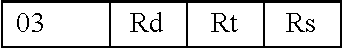

| | |
|---|---|
| 02 | Rd = Rt + Rs + C |
| 43 | Rd = Rt + data16 + C |

Assembler Syntax

| | | |
|---|---|---|
| addc | r4,r4,r3 | |
| addc | r2,r1,#6 | |
| addc,s | r2,r3,r5 | ;set c,n,z,v |

Subtract

SUB

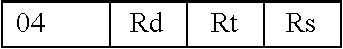

| | |
|---|---|
| 03 | Rd = Rt − Rs |
| 44 | Rd = Rt − data16 |

Assembler Syntax

| | | |
|---|---|---|
| sub | r4,r4,r3 | |
| subI | r2,r1,#6 | |
| sub,s | r2,r3,r5 | ;set c,n,z,v |

SUB with BORROW

SUBC

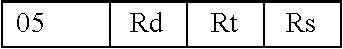

| | |
|---|---|
| 05 | Rd = Rt − Rs − C |
| 45 | Rd = Rt − data16 − C |

Assembler Syntax

| | | |
|---|---|---|
| subc | r4,r4,r3 | |
| subc | r2,r1,#6 | |
| subc,s | r2,r3,r5 | ;set c,n,z,v |

AND

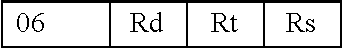

| | |
|---|---|
| 06 | Rd = Rt AND Rs |
| 46 | Rd = Rt AND data16 (upper half of Rd is unchanged) |

Assembler Syntax

| | | |
|---|---|---|
| and | r4,r4,r3 | |
| and | r2,r1,#6 | |
| and,s | r2,r3,r5 | ;set c,n,z |

OR

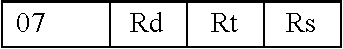

| | |
|---|---|
| 07 | Rd = Rt OR Rs |
| 47 | Rd = Rt OR data16 (upper half of Rd is unchanged) |

Assembler Syntax

| | | |
|---|---|---|
| or | r4,r4,r3 | |
| or | r2,r1,#6 | |
| or,s | r2,r3,r5 | ;set c,n,z |

XOR

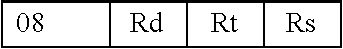

| | |
|---|---|
| 08 | Rd = Rt XOR Rs |
| 48 | Rd = Rt XOR data16 (upper half of Rd is unchanged) |

Assembler Syntax

| | | |
|---|---|---|
| xor | r4,r4,r3 | |
| xor | r2,r1,#6 | |
| xor,s | r2,r3,r5 | ;set c,n,z |

Compare

CMP

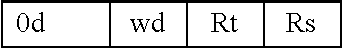

| | |
|---|---|
| 0d | flags (c, n, z) <= Rt − Rs |
| 4d | flags (c, n, z) <= Rt − data16 |
| | (data 16 is sign extended) |

Assembler Syntax

| | |
|---|---|
| cmp | r4,r3 |
| cmp | r2,#6 |

Logical Left Shift

LLS

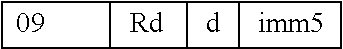

| | |
|---|---|
| 09, d = 0 | Rd = Rd << imm5 |

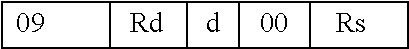

| | |
|---|---|
| 09, d = 1 | Rd = Rd << Rs |

Zeros shift in on right.

Assembler Syntax for LLS

| | | |
|---|---|---|
| lls | r3,#12 | |
| lls | r3,r1 | |
| lls,s | r3,#1 | ;set z,n, c=last bit shifted out |

Logical Right Shift

LRS

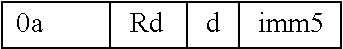

| | |
|---|---|
| 0a, d = 0 | Rd = Rd >> imm5 |

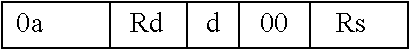

| | |
|---|---|
| 0a, d = 1 | Rd = Rd >> Rs |

Zero shifts in from the left.

Assembler Syntax for ASR

| | | |
|---|---|---|
| lrs | r3,#12 | |
| lrs | r3,r1 | |
| lrs,s | r3,#1 | ;set z,n, c=last bit shifted out on right |

Arithmetic Right Shift

ASR

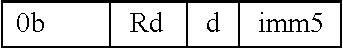

| | |
|---|---|
| 0b, d = O | Rd = Rd >> imm5 |

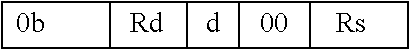

| | |
|---|---|
| 0b, d = 1 | Rd = Rd >> Rs |

Sign bit is replicated on the left as the operand shifts right.

Assembler Syntax for ASR

| | | |
|---|---|---|
| asr | r3,#12 | |
| asr | r3,r1 | |
| asr,s | r3,#1 | ;set z,n, c=last bit shifted out on right |

Rotate left

ROL

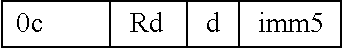

| | |
|---|---|
| 0c, d = 0 | Rd = Rd << imm5 |

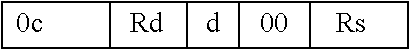

| | |
|---|---|
| 0c, d = 1 | Rd = Rd << Rs |

Bits that shift out on the left, shift in on the right.

Assembler Syntax for ROL

| | | |
|---|---|---|
| rol | r3,#12 | |
| rol | r3,r1 | |
| rol,s | r3,#1 | ;set z,n, c=unchanged |

Branch

BR

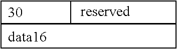

| | |
|---|---|
| 30-3e | The program counter is conditionally loaded |
| | with PC+ data16 |
| 30 | BR always |
| 31 | BEQ if(Z) |
| 32 | BNE if(˜Z) |
| 33 | BCS if(C) |
| 34 | BCC if(˜C) |
| 35 | BMI if(N) |
| 36 | BPL if(˜N) |
| 37 | BVS if(V) |
| 38 | BVC if(˜V) |
| 39 | BHI if(C & ˜Z) |
| 3a | BLS if(˜C \| Z) |
| 3b | BGT if((N == V) & ˜Z) |
| 3c | BGE if(N == V) |
| 3d | BLT if(N == ˜V) |
| 3e | BLE if((N == ˜V) \| Z) |

Assembler Syntax

| | | |
|---|---|---|
| beq | loc_3 | ;assembler calculates offset for symbolic addresses |

Branch to Subroutine

BSR

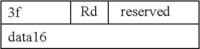

| | |
|---|---|
| 3f | The program counter + 1 is loaded into Rd, |
| | then the program counter is replaced with PC + data16. |

The instruction immediately following BSR is always executed before the branch takes effect. This instruction cannot be a 2-word instruction.

Assembler Syntax

| | |
|---|---|
| bsr | r4,task3 |
| nop | |

<remainder of main program>

halt

task3:

<task3 subroutine>

jmp r4 ;return to main program

HALT

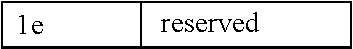

| | | |
|---|---|---|
| 1e | Halt | Execution stops |

Assembler Syntax

halt

The machine becomes idle when halted, but will still respond to enabled interrupts.

DEC, INC, CLR

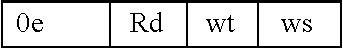

| | |
|---|---|
| 0e, wt = 0 | Rd = 0 |
| 0e, wt = 1 | Rd = Rd + 1 |
| oe, wt = 2 | Rd = Rd − 1 |

Assembler Syntax

| | | |
|---|---|---|
| clr | r1 | |
| inc | r2 | |
| dec | r3 | |
| dec,s | r3 | ;set c,n,z -- v is unchanged |

These instructions replace equivalent 2-word instructions.

What is claimed is:

1. An integrated circuit comprising
an FPGA core;
an interface adapted to receive commands to configure said FPGA core; and
a microcontroller coupled to said FPGA core, said microcontroller configuring said FPGA core responsive to said commands received from said interface.

2. The integrated circuit of claim 1 further comprising a processor unit for directing operations of said integrated circuit.

3. The integrated circuit of claim 2 wherein said interface is adapted to receive said configure commands from said processor.

4. The integrated circuit of claim 1 wherein said interface is further adapted to test said FPGA core, said microcontroller testing said FPGA core responsive to said test commands received from said interface.

5. The integrated circuit of claim 2 wherein said interface is further adapted to test said FPGA core, said microcontroller testing said FPGA core responsive to said test commands received by said interface and wherein said interface is adapted to receive said test commands from said processor.

6. The integrated circuit of claim 4 wherein said microcontroller tests said FPGA core in a predetermined sequence of tests for specific features of said FPGA core.

7. The integrated circuit of claim 6 wherein said FPGA core has a hierarchical architecture and said predetermined sequence of tests corresponds to said hierarchical architecture.

8. The integrated circuit of claim 4 further comprising a plurality of scan chains coupled to said FPGA core for introducing test vectors into said FPGA core and for receiving test results from said FPGA core responsive to said microcontroller.

9. The integrated circuit of claim 8 wherein said scan chains are arranged with respect to at least one predetermined portion of said FPGA core so that a first scan chain introduces a test vector into said portion and a second scan chain receives tests results of said test vector from said portion.

10. The integrated circuit of claim 8 wherein said microcontroller in predetermined sequence introduces said test vectors into said FPGA core and receives test results from said FPGA core through said scan chains.

11. The integrated circuit of claim 10 wherein said FPGA core has a hierarchical architecture and said predetermined sequence corresponds to said hierarchical architecture.
